(19) United States
(12) Patent Application Publication
(10) Pub. No.: US 2018/0190423 A1
(43) Pub. Date: Jul. 5, 2018

(54) COMMON MODE CHOKE COIL

(71) Applicant: Murata Manufacturing Co., Ltd., Nagaokakyo-shi (JP)

(72) Inventors: Noriyuki UEKI, Nagaokakyo-shi (JP); Noboru KATO, Nagaokakyo-shi (JP)

(21) Appl. No.: 15/908,884

(22) Filed: Mar. 1, 2018

Related U.S. Application Data
(63) Continuation of application No. PCT/JP2016/080163, filed on Oct. 12, 2016.

(30) Foreign Application Priority Data
Oct. 16, 2015 (JP) 2015-204612

(51) Int. Cl. H01F 27/28; H01F 17/00

(52) U.S. Cl. CPC H01F 27/2804; H03H 2001/0092; H01F 2017/0093; H01F 17/0013

(57) ABSTRACT

A first coil of a common mode choke coil includes first and second loop-shaped conductors in different layers, and an interlayer connection conductor that connects the first and second loop-shaped conductors. The inner and outer diameters of the second loop-shaped conductor are less than or equal to the inner and outer diameters of the first loop-shaped conductor. A second coil includes third and fourth loop-shaped conductors in different layers, and an interlayer connection conductor that connects the third and fourth loop-shaped conductors. The third loop-shaped conductor is outside the first loop-shaped conductor in the same layer as the first loop-shaped conductor, and the fourth loop-shaped conductor is inside the second loop-shaped conductor in the same layer as the second loop-shaped conductor.

### CROSS REFERENCE TO RELATED APPLICATIONS

This application claims the benefit of priority to Japanese Patent Application No. 2015-204612 filed on Oct. 16, 2015 and is a Continuation Application of PCT Application No. PCT/JP2016/080163 filed on Oct. 12, 2016. The entire contents of each application are hereby incorporated herein by reference.

### BACKGROUND OF THE INVENTION

### 1. Field of the Invention

The present invention relates to a common mode choke coil preferably for use in a high-frequency signal transmission line, for example.

### 2. Description of the Related Art

For example, in a high-speed serial interface, a “differential transmission method” is used in which signals having phases that differ by 180° from each other are transmitted using a pair of signal lines (=a balanced line). In the differential transmission method, radiation noise and external noise are cancelled out in the balanced line, and therefore, there is unlikely to be an effect from such noise. However, a common mode noise current may be generated due to asymmetries between the signal lines depending on the usage environment. A common mode choke coil is used in order to suppress such common mode noise.

A common mode choke coil is typically constructed as a small multilayer chip component that includes two coils that are wound in the same direction. In this case, the two coils are arrayed in the stacking direction inside a multilayer element body.

Furthermore, Japanese Registered Utility Model No. 3093443 discloses a common mode filter that, in particular, achieves small parasitic capacitances and facilitates size reduction.

In the common mode filter disclosed in Japanese Registered Utility Model No. 3093443, anode coils and cathode coils are arranged so as to be stacked in an alternating manner and such that the anode coils and the cathode coils do not overlap. Therefore, parasitic capacitances generated between the anode coils and the cathode coils are suppressed.

However, since the anode coils and the cathode coils cannot be constructed with symmetrical shapes, it is difficult to make the inductances of the anode coils and the cathode coils equal to each other. Conversion between a normal mode signal and common mode noise occurs in the common mode filter when the anode coils and the cathode coils have different inductances.

### SUMMARY OF THE INVENTION

Preferred embodiments of the present invention provide common mode choke coils that are able to achieve size reduction and enable the inductances of a first coil and a second coil to be equal or approximately equal to each other while reducing or preventing parasitic capacitances generated between the first coil and the second coil.

A common mode choke coil according to a preferred embodiment of the present invention includes an element body including a plurality of substrates that are stacked on top of one another, a first coil, and a second coil.

The first coil and the second coil are provided inside the element body and are magnetic-field coupled with each other.

The first coil includes a first loop-shaped conductor and a second loop-shaped conductor, which are provided in different layers from each other, and an interlayer connection conductor that connects the first loop-shaped conductor and the second loop-shaped conductor to each other.

Inner and outer diameters of the second loop-shaped conductor are less than or equal to inner and outer diameters of the first loop-shaped conductor.

The second coil includes a third loop-shaped conductor and a fourth loop-shaped conductor, which are provided in different layers from each other, and an interlayer connection conductor that connects the third loop-shaped conductor and the fourth loop-shaped conductor to each other.

The third loop-shaped conductor is arranged outside the first loop-shaped conductor in the same layer as the first loop-shaped conductor.

The fourth loop-shaped conductor is arranged inside the second loop-shaped conductor in the same layer as the second loop-shaped conductor.

With the above-described configuration, the inductances of the first coil and the second coil are equal or approximately equal to each other, and parasitic capacitances generated between the first coil and the second coil are reduced or prevented.

The outer diameter of the second loop-shaped conductor is preferably smaller than the inner diameter of the first loop-shaped conductor. Consequently, a parasitic capacitance generated between the third loop-shaped conductor and the first loop-shaped conductor is effectively reduced or prevented. Therefore, a reduction in the self-resonant frequency is able to be reduced or prevented, and the common mode choke coil is able to be used in a high-frequency band.

In a common mode choke coil according to a preferred embodiment of the present invention, it is preferable that a plurality of at least either of the first loop-shaped conductor and the second loop-shaped conductor are provided, and that the first loop-shaped conductor and the second loop-shaped conductor be arranged in an alternating manner in a stacking direction, and it is preferable that a plurality of at least either of the third loop-shaped conductor and the fourth loop-shaped conductor are provided, and that the third loop-shaped conductor and the fourth loop-shaped conductor be arranged in an alternating manner in the stacking direction. As a result, the number of turns of each of the first coil and the second coil is at least two turns, and a first coil and a second coil with large prescribed self-inductances are obtained. In addition, the coupling coefficient between the first coil and the second coil is made large.

In a common mode choke coil according to a preferred embodiment of the present invention, relationships a<c and a≥d are preferably satisfied, where a represents an inter-line distance between the first loop-shaped conductor and the third loop-shaped conductor and an inter-line distance between the second loop-shaped conductor and the fourth loop-shaped conductor, c represents an inter-layer distance between first loop-shaped conductors that are adjacent to each other in the stacking direction or an inter-layer distance between third loop-shaped conductors that are adjacent to each other in the stacking direction, and d represents an inter-line distance between the first loop-shaped conductor and the second loop-shaped conductor. Consequently, a parasitic capacitance generated between the first loop-shaped conductor and the second loop-shaped conductor is reduced or prevented, a reduction in the self-resonant frequency of the first coil is reduced or prevented, and the common mode choke coil is able to be used in a high-frequency band. Furthermore, as a result of a d being satisfied, the self-inductance of the first coil will not be too small as compared to the self-inductance of the second coil. In addition, as a result of a<c being satisfied, the self-resonant frequencies of the first coil L1 and the second coil L2 are high, and the common mode choke coil is able to be used in a high-frequency band.

In a common mode choke coil according to a preferred embodiment of the present invention, the substrates are preferably non-magnetic sheets. As a result, loss in a high-frequency band due to the frequency dependence of magnetic permeability is small, and therefore, a common mode choke coil is provided that has low loss in a wide frequency band.

According to preferred embodiments of the present invention, common mode choke coils are obtained that achieve size reduction and enable the inductances of a first coil and a second coil to be equal or approximately equal to each other while reducing or preventing parasitic capacitances generated between the first coil and the second coil.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is an exploded plan view illustrating conductor patterns and other structures of the substrates of a common mode choke coil 101 according to a first preferred embodiment of the present invention.

FIG. 2 is a sectional view of the common mode choke coil 101 taken along X-X in FIG. 1.

FIG. 3 is a circuit diagram illustrating the common mode choke coil 101 of the first preferred embodiment of the present invention as a lumped-parameter circuit.

FIG. 4 is an exploded plan view illustrating conductor patterns and other structures of the substrates of a common mode choke coil 102 according to a second preferred embodiment of the present invention.

FIG. 5 is a sectional view of the common mode choke coil 102 taken along X-X in FIG. 4.

FIG. 6 is an exploded plan view illustrating conductor patterns and other structures of the substrates of a common mode choke coil 103 according to a third preferred embodiment of the present invention.

FIG. 7 is an exploded plan view illustrating conductor patterns and other structures of the substrates of a common mode choke coil 104 according to a fourth preferred embodiment of the present invention.

### DETAILED DESCRIPTION OF THE PREFERRED EMBODIMENTS

Hereafter, a plurality of preferred embodiments of the present invention will be described with reference to the drawings. Identical elements are denoted by identical symbols in the drawings. Taking explanation of important points or ease of understanding into account, the preferred embodiments of the present invention are described in a separate manner for the sake of convenience, but portions of the configurations illustrated in the different preferred embodiments may be substituted for one another or combined with one another. In the second preferred embodiment and preferred embodiments thereafter, description of matters common to the first preferred embodiment is omitted and only the differences are described. In particular, the same operational effects resulting from the same configurations are not repeatedly described in the individual preferred embodiments.

### First Preferred Embodiment

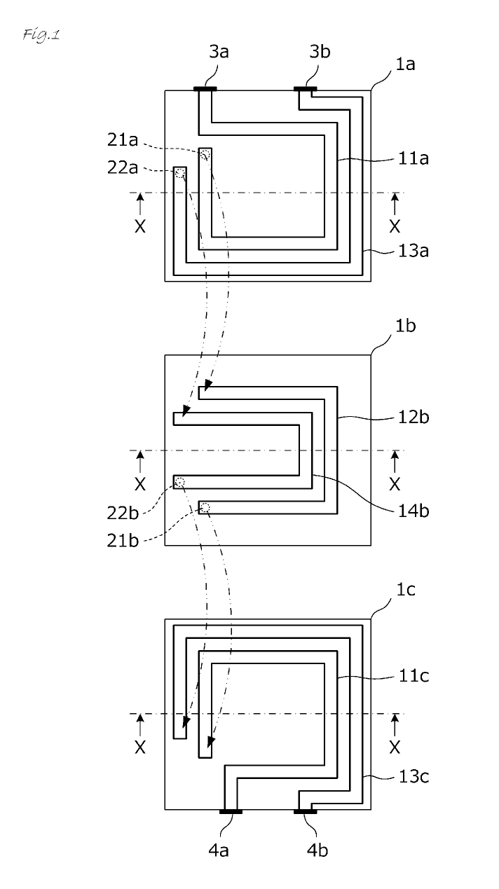

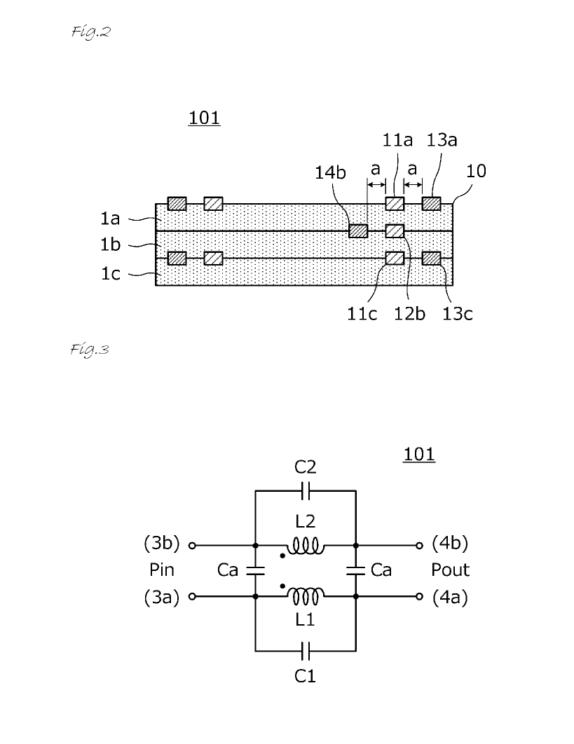

FIG. 1 is an exploded plan view illustrating conductor patterns and other structures of the substrates of a common mode choke coil 101 according to a first preferred embodiment of the present invention. FIG. 2 is a sectional view of the common mode choke coil 101 taken along X-X in FIG. 1.

The common mode choke coil 101 includes a multilayer element body 10, in which non-magnetic substrates 1a, 1b, and 1c are stacked on top of one another, and a first coil and a second coil, which are described later, that are provided inside the multilayer element body 10 and are magnetic-field coupled with each other. A first loop-shaped conductor 11a and a third loop-shaped conductor 13a are provided on the substrate 1a, a second loop-shaped conductor 12b and a fourth loop-shaped conductor 14b are provided on the substrate 1b, and a first loop-shaped conductor 11c and a third loop-shaped conductor 13c are provided on the substrate 1c. In addition, interlayer connection conductors 21a and 22a are provided in the substrate 1a, and interlayer connection conductors 21b and 22b are provided in the substrate 1b.

The first coil includes the first loop-shaped conductor 11a provided on the substrate 1a, the second loop-shaped conductor 12b provided on the substrate 1b, and the first loop-shaped conductor 11c provided on the substrate 1c, and includes the interlayer connection conductors 21a and 21b, which connect the first loop-shaped conductors 11a and 11c and the second loop-shaped conductor 12b to each other. In addition, the second coil includes the third loop-shaped conductor 13a provided on the substrate 1a, the fourth loop-shaped conductor 14b provided on the substrate 1b, and the third loop-shaped conductor 13c provided on the substrate 1c, and includes the interlayer connection conductors 22a and 22b, which connect the third loop-shaped conductors 13a and 13c and the fourth loop-shaped conductor 14b to each other.

On the substrate 1a, the third loop-shaped conductor 13a is arranged outside the first loop-shaped conductor 11a in the same layer as the first loop-shaped conductor 11a, and on the substrate 1c, the third loop-shaped conductor 13c is arranged outside the first loop-shaped conductor 11c in the same layer as the first loop-shaped conductor 11c. In addition, on the substrate 1b, the fourth loop-shaped conductor 14b is arranged inside the second loop-shaped conductor 12b in the same layer as the second loop-shaped conductor 12b.

The first loop-shaped conductors 11a and 11c and the second loop-shaped conductor 12b preferably have the same or substantially the same inner and outer diameters as each other.

A first end of the first loop-shaped conductor 11a extends to one main surface (mounting surface) of the multilayer element body 10 via an end surface electrode 3a, and a first end of the third loop-shaped conductor 13a extends to the one main surface of the multilayer element body 10 via an end surface electrode 3b. Similarly, a first end of the first loop-shaped conductor 11c extends to one main surface (mounting surface) of the multilayer element body 10 via an end surface electrode 4a, and a first end of the third loop-shaped conductor 13c extends to the one main surface of the multilayer element body 10 via an end surface electrode 4b.

With the above-described construction, the inductance generated by the third loop-shaped conductor 13a, which has large inner and outer loop diameters, is large, and the inductance generated by the fourth loop-shaped conductor 14b, which has small inner and outer loop diameters, is small. The inductances generated by the first loop-shaped conductor 11a and the second loop-shaped conductor 12b, which have intermediate inner and outer loop diameters, have intermediate values. Therefore, the inductance of the first coil, which includes the first loop-shaped conductor 11a and the second loop-shaped conductor 12b, and the inductance of the second coil, which includes the third loop-shaped conductor 13a and the fourth loop-shaped conductor 14b, are preferably equal or approximately equal to each other.

In the common mode choke coil 101 of the present preferred embodiment, the first loop-shaped conductors 11a and 11c and the second loop-shaped conductor 12b are preferably arranged in an alternating manner in the stacking direction. Similarly, the third loop-shaped conductors 13a and 13c and the fourth loop-shaped conductor 14b are preferably arranged in an alternating manner in the stacking direction. As a result, the number of turns of each of the first coil and the second coil is preferably at least two turns, for example, and a first coil and a second coil having large prescribed self-inductances are obtained. In addition, the coupling coefficient between the first coil and the second coil is large.

If we also take into consideration the first loop-shaped conductors 11a and 11c and the third loop-shaped conductors 13a and 13c, which are adjacent to each other in the stacking direction, the reason that the inductance of the first coil and the inductance of the second coil described above are equal or approximately equal to each other may also be explained in the following manner.

The inner and outer loop diameters of the first coil defined by the first loop-shaped conductors 11a and 11c and the second loop-shaped conductor 12b are small. Therefore, if we consider just these inner and outer loop diameters, the inductances tend to be small. However, self-induction is large due to an inter-conductor distance b between the first loop-shaped conductors 11a and 11c and the second loop-shaped conductor 12b being small. On the other hand, the third loop-shaped conductors 13a and 13c have large inner and outer loop diameters and, therefore, tend to have large inductances, but an inter-conductor distance c between the third loop-shaped conductors 13a and 13c is large, and therefore, self-induction is reduced or prevented. In other words, the difference in inner and outer loop diameters between the loop-shaped conductors is canceled out by the difference in self-induction, and as a result, the inductance of the first coil and the inductance of the second coil are equal or approximately equal to each other.

As illustrated in FIG. 2, the common mode choke coil 101 of the present preferred embodiment is preferably constructed such that the loop-shaped conductors 11a, 12b, and 11c included in the first coil and the loop-shaped conductors 13a, 14b, and 13c included in the second coil do not overlap in plan view. Therefore, parasitic capacitances generated between the first coil L1 and the second coil L2 are reduced or prevented.

As illustrated in FIG. 2, in the common mode choke coil 101 of the present preferred embodiment, an inter-line distance a between first loop-shaped conductors 11a and 11c and the third loop-shaped conductors 13a and 13c and an inter-line distance a between the second loop-shaped conductor 12b and the fourth loop-shaped conductor 14b are preferably equal or substantially equal to each other. Therefore, as described below, the capacitances generated between the first coil and the second coil are equal or approximately equal to each other on the input and output sides.

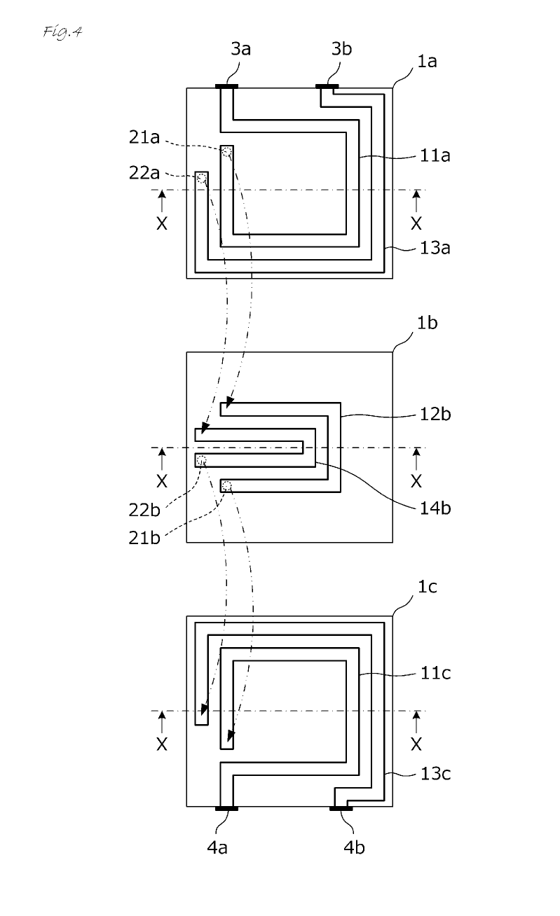

FIG. 3 is a circuit diagram illustrating the common mode choke coil 101 of the present preferred embodiment as a lumped-parameter circuit. The common mode choke coil 101 is a circuit in which first ends of the first coil L1 and the second coil L2 define input ports Pin, and second ends of the first coil L1 and the second coil L2 define output ports Pout. A capacitance Ca is generated between the input ports Pin and a capacitance Ca is generated between the output ports Pout, and a capacitance C1 is generated between the two ends of the first coil L1 and a capacitance C2 is generated between the two ends of the second coil L2.

The capacitance Ca generated between the input ports Pin and the capacitance Ca generated between the output ports Pout are preferably equally or substantially equally distributed among the loop-shaped conductors 11a, 12b, and 11c included in the first coil and the loop-shaped conductors 13a, 14b, and 13c included in the second coil as illustrated in FIG. 2. Therefore, as illustrated in FIG. 3, the capacitance Ca on the input side and the capacitance Ca on the output side when the common mode choke coil 101 is represented as a lumped-parameter circuit are equal or approximately equal to each other. Consequently, conversion between common mode noise and a normal mode signal (noise) due to a capacitance imbalance is reduced or prevented.

### Second Preferred Embodiment

In a second preferred embodiment of the present invention, an example of a common mode choke coil including different loop-shaped conductor patterns from those in the first preferred embodiment is illustrated.

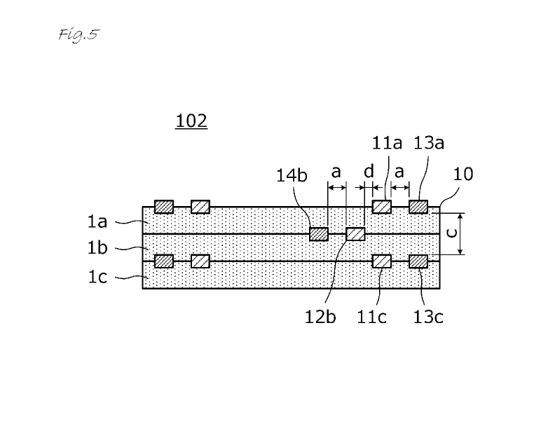

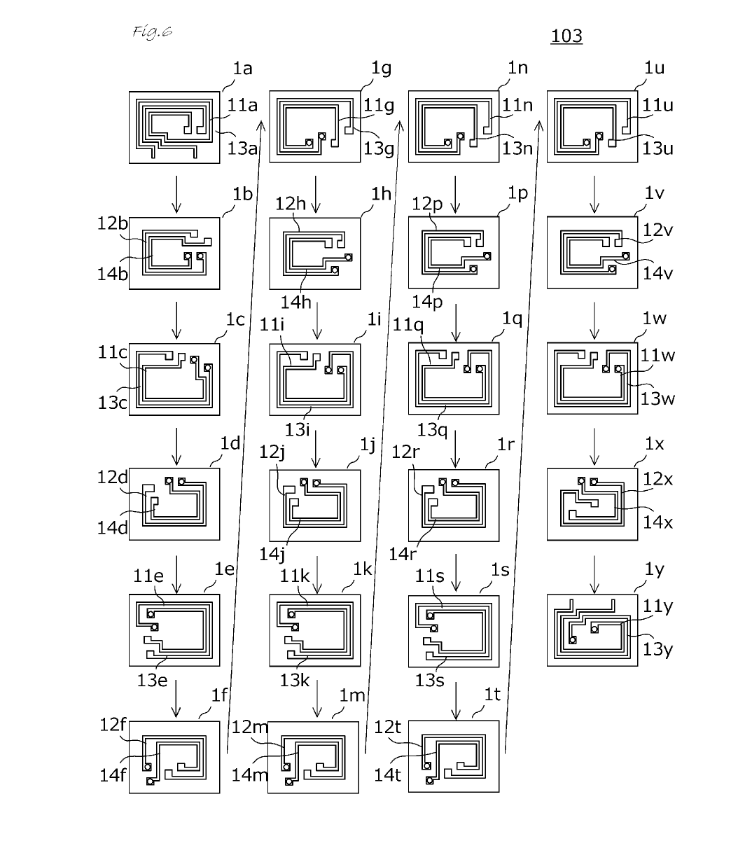

FIG. 4 is an exploded plan view illustrating conductor patterns and other structures of the substrates of a common mode choke coil 102 according to the second preferred embodiment. FIG. 5 is a sectional view of the common mode choke coil 102 taken along X-X in FIG. 4.

The common mode choke coil 102 includes a multilayer element body 10, in which non-magnetic substrates 1a, 1b, and 1c are stacked on top of one another, and a first coil and a second coil, which are described later, that are provided inside the multilayer element body 10 and are magnetic-field coupled with each other. A first loop-shaped conductor 11a and a third loop-shaped conductor 13a are provided on the substrate 1a, a second loop-shaped conductor 12b and a fourth loop-shaped conductor 14b are provided on the substrate 1b, and a first loop-shaped conductor 11c and a third loop-shaped conductor 13c are provided on the substrate 1c. In addition, interlayer connection conductors 21a and 22a are provided in the substrate 1a, and interlayer connection conductors 21b and 22b are provided in the substrate 1b.

In particular, the shapes and sizes of the second loop-shaped conductor 12b and the fourth loop-shaped conductor 14b differ from those in the example illustrated in FIG. 1 in the first preferred embodiment.

On the substrate 1a, the third loop-shaped conductor 13a is arranged outside the first loop-shaped conductor 11a in the same layer as the first loop-shaped conductor 11a, and on the substrate 1c, the third loop-shaped conductor 13c is arranged outside the first loop-shaped conductor 11c in the same layer as the first loop-shaped conductor 11c. In addition, on the substrate 1b, the fourth loop-shaped conductor 14b is arranged inside the second loop-shaped conductor 12b in the same layer as the second loop-shaped conductor 12b.

The inner and outer loop diameters of the second loop-shaped conductor 12b are preferably smaller than the inner and outer loop diameters of the first loop-shaped conductors 11a and 11c. In this preferred embodiment, the outer loop diameter of the second loop-shaped conductor 12b is preferably smaller than the inner loop diameters of the first loop-shaped conductors 11a and 11c. The rest of the construction is the same or substantially the same as that of the common mode choke coil 101 described in the first preferred embodiment. An equivalent circuit of the common mode choke coil 102 is the same or substantially the same as that illustrated in FIG. 3.

With the above-described construction, the inductance generated by the third loop-shaped conductor 13a, which has large inner and outer loop diameters, is large, and the inductance generated by the fourth loop-shaped conductor 14b, which has small inner and outer loop diameters, is small. The inductances generated by the first loop-shaped conductor 11a and the second loop-shaped conductor 12b, which have intermediate inner and outer loop diameters, have intermediate values. Therefore, the inductance of the first coil L1, which includes the first loop-shaped conductor 11a and the second loop-shaped conductor 12b, and the inductance of the second coil L2, which includes the third loop-shaped conductor 13a and the fourth loop-shaped conductor 14b, are preferably equal or approximately equal to each other.

In the common mode choke coil 102 of the present preferred embodiment, the first loop-shaped conductors 11a and 11c and the second loop-shaped conductor 12b are preferably arranged in an alternating manner in the stacking direction similarly to the common mode choke coil 101 of the first preferred embodiment. Similarly, the third loop-shaped conductors 13a and 13c and the fourth loop-shaped conductor 14b are preferably arranged in an alternating manner in the stacking direction. As a result, the number of turns of each of the first coil and the second coil is preferably at least two turns, for example, and a first coil and a second coil having a large prescribed self-inductances is obtained. In addition, the coupling coefficient between the first coil and the second coil is made large.

If we also take into consideration the first loop-shaped conductors 11a and 11c and the third loop-shaped conductors 13a and 13c, which are adjacent to each other in the stacking direction, the reason that the inductance of the first coil and the inductance of the second coil described above are equal or approximately equal to each other may be similarly explained by the fact that the difference in inner and outer loop diameters between the loop-shaped conductors is cancelled out by the difference in self-induction, as in the common mode choke coil 101 of the first preferred embodiment.

As illustrated in FIG. 5, in the common mode choke coil 102 of the present preferred embodiment, the first loop-shaped conductors 11a and 11c and the second loop-shaped conductor 12b preferably do not overlap in plan view and are separated by an inter-line distance d.

Thus, since the first loop-shaped conductors 11a and 11c and the second loop-shaped conductor 12b do not overlap in plan view, capacitances generated between the lines of the loop-shaped conductors 11a, 12b and 11c included in the first coil are reduced or prevented. Consequently, parasitic capacitances generated between the first loop-shaped conductors and the second loop-shaped conductor are reduced or prevented, and lowering of the self-resonant frequency of the first coil is reduced or prevented. Therefore, the common mode choke coil is able to be used in a high-frequency band.

Furthermore, an inter-line distance a between the first loop-shaped conductors 11a and 11c and the third loop-shaped conductors 13a and 13c and an inter-line distance a between the second loop-shaped conductor 12b and the fourth loop-shaped conductor 14b are preferably equal or substantially equal to each other. Therefore, the capacitance Ca on the input side and the capacitance Ca on the output side illustrated in FIG. 3 are equal or approximately equal to each other as in the common mode choke coil 101 of the first preferred embodiment.

In addition, an inter-layer distance c between the first loop-shaped conductor 11a and the first loop-shaped conductor 11c, which are adjacent to each other in the stacking direction, and an inter-layer distance c between the third loop-shaped conductor 13a and the third loop-shaped conductor 13c, which are adjacent to each other in the stacking direction, are preferably equal or substantially equal to each other. Path lengths of the first loop-shaped conductors 11a and 11c are shorter than path lengths of the third loop-shaped conductors 13a and 13c, and capacitances are generated between the first loop-shaped conductors 11a and 11c and the second loop-shaped conductor 12b. As a result, an inter-line capacitance of the first coil L1 and an inter-line capacitance of the second coil L2 are preferably equal or approximately equal to each other, and therefore, a capacitance (stray capacitance) C1 between the two ends of the first coil L1 and a capacitance (stray capacitance) C2 between the two ends of the second coil L2 illustrated in FIG. 3 are preferably equal or approximately equal to each other. Consequently, conversion of common mode noise into a normal mode signal (noise) due to an imbalance between the capacitances C1 and C2 is also reduced or prevented.

In the common mode choke coil 102 of the present preferred embodiment, relationships a<c and a≥d, for example, are preferably satisfied between the dimensions a, c, and d illustrated in FIG. 5. As a result of a≥d, the self-inductance of the first coil will not become too small as compared to the self-inductance of the second coil. Furthermore, as a result of a<c, the stray capacitance C1 of the first coil L1 and the stray capacitance C2 of the second coil L2 illustrated in FIG. 3 is small (at least the effect thereof is small as compared to that of the input/output capacitances Ca). As a result, the self-resonant frequencies of the first coil L1 and the second coil L2 is high, and the common mode choke coil is able to be used in a high-frequency band.

### Third Preferred Embodiment

In a third preferred embodiment of the present invention, a common mode choke coil is described that is of the type illustrated in the first preferred embodiment in which four or more substrates are provided and the number of turns of each coil is three or more, for example.

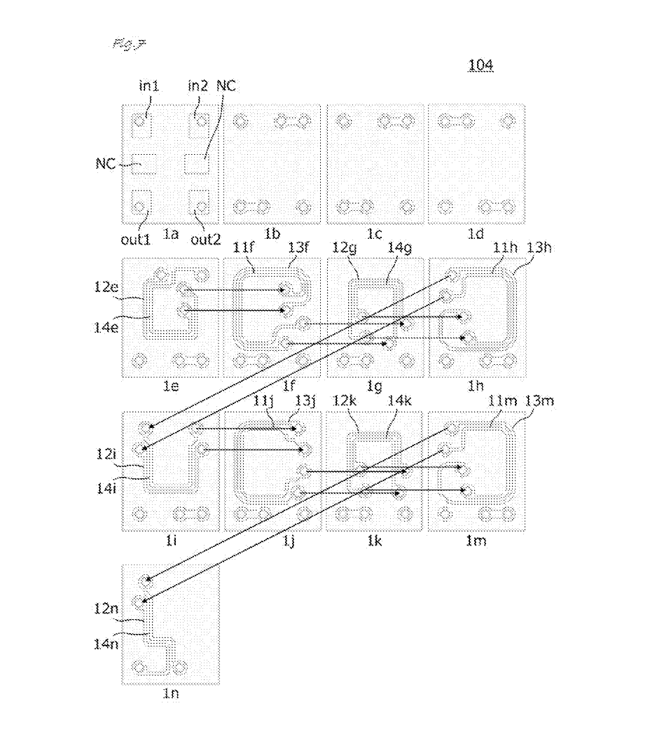

FIG. 6 is an exploded plan view illustrating conductor patterns and other structures of the substrates of a common mode choke coil 103 according to the third preferred embodiment.

The common mode choke coil 103 includes a multilayer element body in which substrates 1a to 1y are stacked on top of one another, and a first coil and a second coil, which are described later, that are provided inside the multilayer element body and are magnetic-field coupled with each other. In FIG. 6, loop-shaped conductors 11a, 11c, 11e, 11g, 11i, 11k, 11n, 11q, 11s, 11u, 11w, and 11y are first loop-shaped conductors, and loop-shaped conductors 12b, 12d, 12f, 12h, 12j, 12m, 12p, 12r, 12t, 12v, and 12x are second loop-shaped conductors. In addition, loop-shaped conductors 13a, 13c, 13e, 13g, 13i, 13k, 13n, 13q, 13s, 13u, 13w, and 13y are third loop-shaped conductors, and loop-shaped conductors 14b, 14d, 14f, 14h, 14j, 14m, 14p, 14r, 14t, 14v, 14x are fourth loop-shaped conductors. Illustration of external connection terminals is omitted from FIG. 6.

The first loop-shaped conductors and the third loop-shaped conductors are provided on the odd substrates 1a, 1c, 1e, 1g, 1, 1k, 1n, 1q, 1s, 1u, 1w, and 1y. The second loop-shaped conductors and the fourth loop-shaped conductors are provided on the even substrates 1b, 1d, 1f, 1h, 1j, 1m, 1p, 1r, 1t, 1v, and 1x.

In addition, interlayer connection conductors are provided in the substrates, and the first coil includes the first loop-shaped conductors 11a, 11c, 11e, 11g, 11i, 11k, 11n, 11q, 11s, 11u, 11w, and 11y, the third loop-shaped conductors 13a, 13c, 13e, 13g, 13i, 13k, 13n, 13q, 13s, 13u, 13w, and 13y, and the interlayer connection conductors that connect the first and third loop-shaped conductors to one another. Similarly, the second coil includes the second loop-shaped conductors 12b, 12d, 12f, 12h, 12j, 12m, 12p, 12r, 12t, 12v, and 12x, the fourth loop-shaped conductors 14b, 14d, 14f, 14h, 14j, 14m, 14p, 14r, 14t, 14v, and 14x, and the interlayer connection conductors that connect the second loop-shaped conductors and the fourth loop-shaped conductors to one another.

On the individual substrates, the third loop-shaped conductors 13a, 13c, 13e, 13g, 13i, 13k, 13n, 13q, 13s, 13u, 13w, and 13y are respectively arranged outside the first loop-shaped conductors 11a, 11c, 11e, 11g, 11i, 11k, 11n, 11q, 11s, 11u, 11w, and 11y in the same layers as the first loop-shaped conductors 11a, 11c, 11e, 11g, 11i, 11k, 11n, 11q, 11s, 11u, 11w, and 11y.

In addition, on the individual substrates, the fourth loop-shaped conductors 14b, 14d, 14f, 14h, 14j, 14m, 14p, 14r, 14t, 14v, and 14x are respectively arranged inside the second loop-shaped conductors 12b, 12d, 12f, 12h, 12j, 12m, 12p, 12r, 12t, 12v, and 12x in the same layers as the second loop-shaped conductors 12b, 12d, 12f, 12h, 12j, 12m, 12p, 12r, 12t, 12v, and 12x.

The first loop-shaped conductors 11a, 11c, 11e, 11g, 11i, 11k, 11n, 11q, 11s, 11u, 11w, and 11y and the second loop-shaped conductors 12b, 12d, 12f, 12h, 12j, 12m, 12p, 12r, 12t, 12v, and 12x preferably have the same or substantially the same inner and outer loop diameters.

With the above-described configuration, the inductances generated by the third loop-shaped conductors, which have large inner and outer loop diameters, are large, and the inductances generated by the fourth loop-shaped conductors, which have small inner and outer loop diameters, are small. The inductances generated by the first loop-shaped conductors and the second loop-shaped conductors, which have intermediate inner and outer loop diameters, have intermediate values. Therefore, the inductance of the first coil, which includes the first loop-shaped conductors and the second loop-shaped conductors, and the inductance of the second coil, which includes the third loop-shaped conductors and the fourth loop-shaped conductors, are preferably equal or approximately equal to each other.

In the common mode choke coil 103 of the present preferred embodiment, a first coil and a second coil having large prescribed self-inductances are obtained. In addition, the coupling coefficient between the first coil and the second coil is large.

### Fourth Preferred Embodiment

In a fourth preferred embodiment of the present invention, a common mode choke coil is described that is of the type illustrated in the second preferred embodiment in which four or more substrates are provided and the number of turns of each coil is three or more.

FIG. 7 is an exploded plan view illustrating conductor patterns and other structures of the substrates of a common mode choke coil 104 according to the fourth preferred embodiment.

The common mode choke coil 104 includes a multilayer element body in which substrates 1a to 1n are stacked on top of one another, and a first coil and a second coil that are provided inside the multilayer element body and are magnetic-field coupled with each other.

In FIG. 7, input terminals in1 and in2, output terminals out1 and out2, and unused terminals NC are provided on the substrate 1a. Conductor patterns, which connect the input terminals in1 and in2 to prescribed loop-shaped conductor patterns, are respectively provided on the substrates 1b, 1c, and 1d. In addition, conductor patterns, which connect the output terminals out1 and out2 to prescribed loop-shaped conductor patterns, are provided on the substrates 1b to 1m.

In FIG. 7, loop-shaped conductors 11f, 11h, 11j, and 11m are first loop-shaped conductors, and loop-shaped conductors 12e, 12g, 12i, 12k, and 12n are second loop-shaped conductors. In addition, loop-shaped conductors 13f, 13h, 13j, and 13m are third loop-shaped conductors, and loop-shaped conductors 14e, 14g, 14i, 14k, and 14n are fourth loop-shaped conductors.

Although the loop-shaped conductors 12n and 14n provided on the substrate 1n are conductor patterns that extend through less than about ½ a turn, these types of conductor patterns are also referred to as loop-shaped conductor patterns in the description of preferred embodiments of the present invention.

The first loop-shaped conductors and the third loop-shaped conductors are provided on the even substrates 1f, 1h, 1j, and 1m. The second loop-shaped conductors and the fourth loop-shaped conductors are provided on the odd substrates le, 1g, 1i, 1k, and 1n.

In addition, interlayer connection conductors are provided in the substrates, and the first coil includes the first loop-shaped conductors 11f, 11h, 11j, and 11m, the third loop-shaped conductors 13f, 13h, 13j, and 13m, and the interlayer connection conductors that connect the first loop-shaped conductors and the third loop-shaped conductors to one another. Similarly, the second coil includes the second loop-shaped conductors 12e, 12g, 12i, 12k, and 12n, the fourth loop-shaped conductors 14e, 14g, 14i, 14k, and 14n, and the interlayer connection conductors that connect the second loop-shaped conductors and the fourth loop-shaped conductors to one another.

On the individual substrates, the third loop-shaped conductors 13f, 13h, 13j, and 13m are respectively arranged outside the first loop-shaped conductors 11f, 11h, 11j, and 11m in the same layers as the first loop-shaped conductors 11f, 11h, 11j, and 11m.

In addition, on the individual substrates, the fourth loop-shaped conductors 14e, 14g, 14i, 14k, and 14n are respectively arranged inside the second loop-shaped conductors 12e, 12g, 12i, 12k, and 12n in the same layers as the second loop-shaped conductors 12e, 12g, 12i, 12k, and 12n.

With the above-described configuration, the inductances generated by the third loop-shaped conductors, which have large inner and outer loop diameters, are large, and the inductances generated by the fourth loop-shaped conductors, which have small inner and outer loop diameters, are small. The inductances generated by the first loop-shaped conductors and the second loop-shaped conductors, which have intermediate inner and outer loop diameters, have intermediate values. Therefore, the inductance of the first coil, which includes the first loop-shaped conductors and the second loop-shaped conductors, and the inductance of the second coil, which includes the third loop-shaped conductors and the fourth loop-shaped conductors, are preferably equal or approximately equal to each other.

In the common mode choke coil 104 of the present preferred embodiment, a first coil and a second coil having large prescribed self-inductances are obtained. In addition, the coupling coefficient between the first coil and the second coil is large.

In the preferred embodiments of the present invention described above, non-magnetic substrates are preferably used, but magnetic substrates, such as ferrite ceramic substrates, for example, may be used in order to reduce the number of substrates and obtain a prescribed large inductance when the coil is to be used in a comparatively low frequency band.

Finally, the descriptions of the preferred embodiments of the present invention are illustrative in all points and are not restrictive. A person skilled in the art can make modifications and changes as appropriate. For example, portions of the constructions described in different preferred embodiments may be substituted for one another or combined with one another.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A common mode choke coil comprising:
an element body including a plurality of substrates that are stacked on top of one another;
a first coil; and
a second coil; wherein the first coil and the second coil are provided inside the element body and are magnetic field-coupled with each other;
the first coil includes a first loop-shaped conductor and a second loop-shaped conductor, which are provided at different substrates of the plurality of substrates from each other, and an interlayer connection conductor that connects the first loop-shaped conductor and the second loop-shaped conductor to each other;
inner and outer diameters of the second loop-shaped conductor are less than or equal to inner and outer diameters of the first loop-shaped conductor;
the second coil includes a third loop-shaped conductor and a fourth loop-shaped conductor, which are provided at different substrates of the plurality of substrates from each other, and an interlayer connection conductor that connects the third loop-shaped conductor and the fourth loop-shaped conductor to each other;
the third loop-shaped conductor is arranged outside the first loop-shaped conductor at a same substrate as the first loop-shaped conductor; and
the fourth loop-shaped conductor is arranged inside the second loop-shaped conductor at a same substrate as the second loop-shaped conductor.

2. The common mode choke coil according to claim 1, wherein
the first coil includes a number of turns of at least two turns in three adjacent layers that include the first loop-shaped conductor and the second loop-shaped conductor; and
the second coil includes a number of turns of at least two turns in three adjacent layers that include the third loop-shaped conductor and the fourth loop-shaped conductor.

3. The common mode choke coil according to claim 1, wherein the outer diameter of the second loop-shaped conductor is smaller than the inner diameter of the first loop-shaped conductor.

4. The common mode choke coil according to claim 1, wherein
a plurality of at least one of the first loop-shaped conductor and the second loop-shaped conductor are provided, and the first loop-shaped conductor and the second loop-shaped conductor are arranged in an alternating manner in a stacking direction of the plurality of substrates; and
a plurality of at least one of the third loop-shaped conductor and the fourth loop-shaped conductor is provided, and the third loop-shaped conductor and the fourth loop-shaped conductor are arranged in an alternating manner in the stacking direction.

5. The common mode choke coil according to claim 4, wherein relationships of a<c and a≥d are satisfied, where a represents an inter-line distance between the first loop-shaped conductor and the third loop-shaped conductor and an inter-line distance between the second loop-shaped conductor and the fourth loop-shaped conductor, c represents an inter-layer distance between first loop-shaped conductors that are adjacent to each other in the stacking direction or an inter-layer distance between third loop-shaped conductors that are adjacent to each other in the stacking direction, and d represents an inter-line distance between the first loop-shaped conductor and the second loop-shaped conductor.

6. The common mode choke coil according to claim 1, wherein the substrates are non-magnetic sheets.

7. The common mode choke coil according to claim 1, wherein the first loop-shaped conductor and the second loop-shaped conductor have the same or substantially the same inner and outer diameters.

8. The common mode choke coil according to claim 1, wherein a first end of the first loop-shaped conductor extends to a one main surface of the multilayer element body via an end surface electrode, and a first end of the third loop-shaped conductor extends to the one main surface of the multilayer element body via another end surface electrode.

9. The common mode choke coil according to claim 1, wherein the first loop-shaped conductor and the second loop-shaped conductor of the first coil do not overlap the third loop-shaped conductor and the fourth loop-shaped conductor of the second coil.

10. A common mode choke coil comprising:
an element body including a plurality of substrates that are stacked on top of one another;
a first coil; and
a second coil; wherein the first coil and the second coil are provided inside the element body and are magnetic field-coupled with each other;
the first coil includes a first loop-shaped conductor and a second loop-shaped conductor, which are provided at different substrates of the plurality of substrates from each other, and an interlayer connection conductor that connects the first loop-shaped conductor and the second loop-shaped conductor to each other;
inner and outer diameters of the second loop-shaped conductor are less than or equal to inner and outer diameters of the first loop-shaped conductor;
the second coil includes a third loop-shaped conductor and a fourth loop-shaped conductor, which are provided at different substrates of the plurality of substrates from each other, and an interlayer connection conductor that connects the third loop-shaped conductor and the fourth loop-shaped conductor to each other;
an inner diameter of the third loop-shaped conductor is larger than outer diameters of both of the first loop-shaped conductor and the second loop-shaped conductor; and
an outer diameter of the fourth loop-shaped conductor is smaller than inner diameters of both of the first loop-shaped conductor and the second loop-shaped conductor.

11. The common mode choke coil according to claim 10, wherein
the third loop-shaped conductor is arranged at the same substrate as the first loop-shaped conductor; and
the fourth loop-shaped conductor is arranged at the same substrate as the second loop-shaped conductor.

12. The common mode choke coil according to claim 10, wherein
the first coil includes a number of turns of at least two turns in three adjacent substrates that include the first loop-shaped conductor and the second loop-shaped conductor; and
the second coil includes a number of turns of at least two turns in three adjacent substrates that include the third loop-shaped conductor and the fourth loop-shaped conductor.

13. The common mode choke coil according to claim 10, wherein the outer diameter of the second loop-shaped conductor is smaller than the inner diameter of the first loop-shaped conductor.

14. The common mode choke coil according to claim 10, wherein a plurality of at least one of the first loop-shaped conductor and the second loop-shaped conductor are provided, and the first loop-shaped conductor and the second loop-shaped conductor are arranged in an alternating manner in a stacking direction of the plurality of substrates; and
a plurality of at least one of the third loop-shaped conductor and the fourth loop-shaped conductor is provided, and the third loop-shaped conductor and the fourth loop-shaped conductor are arranged in an alternating manner in the stacking direction.

15. The common mode choke coil according to claim 14, wherein relationships of a <c and a d are satisfied, where a represents an inter-line distance between the first loop-shaped conductor and the third loop-shaped conductor and an inter-line distance between the second loop-shaped conductor and the fourth loop-shaped conductor, c represents an inter-layer distance between first loop-shaped conductors that are adjacent to each other in the stacking direction or an inter-layer distance between third loop-shaped conductors that are adjacent to each other in the stacking direction, and d represents an inter-line distance between the first loop-shaped conductor and the second loop-shaped conductor.

16. The common mode choke coil according to claim 10, wherein the substrates are non-magnetic sheets.

17. The common mode choke coil according to claim 10, wherein the first loop-shaped conductor and the second loop-shaped conductor have the same or substantially the same inner and outer diameters.

18. The common mode choke coil according to claim 10, wherein a first end of the first loop-shaped conductor extends to a one main surface of the multilayer element body via an end surface electrode, and a first end of the third loop-shaped conductor extends to the one main surface of the multilayer element body via another end surface electrode.

19. The common mode choke coil according to claim 10, wherein the first loop-shaped conductor and the second loop-shaped conductor of the first coil do not overlap the third loop-shaped conductor and the fourth loop-shaped conductor of the second coil.
